(19) United States
(12) Patent Application Publication
(10) Pub. No.: US 2022/0344434 A1
(43) Pub. Date: Oct. 27, 2022

(54) Display Circuit and Display Apparatus

(71) Applicant: CHONGQING KONKA PHOTOELECTRIC TECHNOLOGY RESEARCH INSTITUTE CO., LTD., Chongqing (CN)

(72) Inventor: Shisong ZHENG, Chongqing (CN)

(21) Appl. No.: 17/263,884

(22) PCT Filed: Jan. 20, 2020
(86) PCT No.: PCT/CN2020/073082

§ 371 Date: Jan. 27, 2021

(30) Foreign Application Priority Data
Jan. 15, 2020 (CN) 202010042536.5

(51) Int. Cl. H01L 27/32

(52) U.S. Cl. CPC H01L 27/3276

(57) ABSTRACT

Provided are a display circuit and a display apparatus. The display circuit comprises a plurality of micro devices connected in a common anode manner or a common cathode manner, wherein a cathode of each of the plurality of micro devices is connected to a first transistor, an anode of the micro device is connected to a second transistor, and the first transistor and the second transistor cooperate to generate a reverse bias voltage to initialize the micro device. The display apparatus comprises the display circuit.

### TECHNICAL FIELD

The present disclosure relates to the field of display technology, and particularly to a display circuit and a display apparatus.

### BACKGROUND

Electroluminescence (EL) devices comprise devices such as Organic Light-Emitting Diodes (OLED) and Light-Emitting Diodes (LED). In recent years, the EL devices have been widely used for manufacturing display products. Compared with traditional Cathode Ray Tube (CRT) displays, Liquid Crystal Displays (LCD), etc., the EL devices show better optical characteristics, lower power consumption performance and better product shape plasticity in applications. The common electrode architecture used for light emission of the EL devices provides an important driving environment element for a most basic display, and a power saving application is further developed by combining the most basic display and the common electrode architecture. The support of power saving application becomes an important advantage for introducing the products into the terminal market. However, as shown in FIG. 1 to FIG. 5, in panel architecture adopted in related art, after a driving operation, the non-ideal effect of signals is reflected on the EL device, so that the EL device generates background luminance before the next operation sequence due to the charges left over from the previous operation sequence, causing decrease of the contrast.

Therefore, the related art needs to be improved and developed.

### SUMMARY

In view of the described deficiencies of the related art, an object of the embodiments of the present disclosure is to provide a display circuit and a display apparatus, so as to solve the problem (i.e., the non-ideal effect of signals is reflected on the EL device, so that the EL device generates background luminance before the next operation sequence due to the charges left over from the previous operation sequence, causing decrease of the contrast).

The technical solution of the embodiments of the present disclosure is described as follows.

A display circuit comprises a plurality of micro devices connected in a common anode manner or a common cathode manner. A cathode of each of the plurality of micro devices is connected to a first transistor, an anode of the micro device is connected to a second transistor, and the first transistor and the second transistor cooperate to generate a reverse bias voltage to initialize the micro device.

In some exemplary configurations of the present disclosure, when the plurality of micro devices are connected in the common cathode manner, a gate of the first transistor is connected to a first common scanning signal line, and a gate of the second transistor is connected to a second common scanning signal line; a drain of the first transistor is connected to the cathode of the micro device, and a source of the first transistor is connected to a common cathode power source signal line; a drain of the second transistor is connected to a direct current source signal line of the micro device, and a source of the second transistor is connected to the anode of the micro device.

In some exemplary configurations of the present disclosure, anodes of the plurality of micro devices are connected to grayscale control signal lines, wherein the grayscale control signal lines comprise red grayscale control signal lines, green grayscale control signal lines and blue grayscale control signal lines.

In some exemplary configurations of the present disclosure, the display circuit further comprises a plurality of sub-circuit units. The plurality of sub-circuit units are arranged corresponding to the plurality of micro devices. One end of each of the plurality of sub-circuit units is connected to a common anode power source signal line, and the other ends of the plurality of sub-circuit units are connected to anodes of the plurality of micro devices and the source of the second transistor. The grayscale control signal line is connected to the sub-circuit unit. Herein, the sub-circuit unit is composed of a third transistor and a capacitor.

In some exemplary configurations of the present disclosure, the display circuit comprises multiple groups of micro device components. Each of the multiple groups of micro device components comprises the first transistor, the second transistor, the micro device and the sub-circuit unit. The common anode power source signal line comprises a first common anode power source signal line, a second common anode power source signal line, a third common anode power source signal line and an Nth common anode power source signal line. One ends of the plurality of sub-circuit units are correspondingly connected to the first common anode power source signal line, the second common anode power source signal line, the third common anode power source signal line and the Nth common anode power source signal line, respectively, and the other ends of the plurality of sub-circuit units are connected to anodes of the plurality of micro devices, wherein N is an integer.

In some exemplary configurations of the present disclosure, when the plurality of micro devices are connected in the common anode manner, a gate of the first transistor is connected to a second common scanning signal line, and a gate of the second transistor is connected to a first common scanning signal line; a drain of the first transistor is connected to the cathode of the micro device, and a source of the first transistor is connected to a direct current source signal line of the micro device; and a drain of the second transistor is connected to a common anode power source signal line, and a source of the second transistor is connected to the anode of the micro device.

In some exemplary configurations of the present disclosure, cathodes of the plurality of micro devices are connected to grayscale control signal lines, wherein the grayscale control signal lines comprise red grayscale control signal lines, green grayscale control signal lines and blue grayscale control signal lines.

In some exemplary configurations of the present disclosure, the display circuit further comprises a plurality of sub-circuit units. The plurality of sub-circuit units are arranged corresponding to the plurality of micro devices. One end of each of the plurality of sub-circuit units is connected to the common cathode power source signal line, and the other end of the sub-circuit unit is connected to the cathode of the micro device and the drain of the first transistor. The grayscale control signal line is connected to the sub-circuit unit. Herein, the sub-circuit unit is composed of a third transistor and a capacitor.

In some exemplary configurations of the present disclosure, the display circuit comprises multiple groups of micro device components. Each of the multiple groups of micro device components comprises the first transistor, the second transistor, the micro device and the sub-circuit unit. The common cathode power source signal line comprises a first common cathode power source signal line, a second common cathode power source signal line, a third common cathode power source signal line, and an Nth common cathode power source signal line. One ends of the plurality of sub-circuit units are correspondingly connected to the first common cathode power source signal line, the second common cathode power source signal line, the third common cathode power source signal line and the Nth common anode power source signal line, and the other ends of the plurality of sub-circuit units are connected to cathodes of the plurality of micro devices, wherein N is an integer.

In some exemplary configurations of the present disclosure, the first transistor and the second transistor are one or more of a p-channel Thin Film Transistor (p-TFT), an n-channel TFT (n-TFT), a p-channel Metal Oxide Semiconductor (p-MOS), and an n-channel MOS (n-MOS).

In some exemplary configurations of the present disclosure, the plurality of micro devices are electroluminescent devices.

The embodiments of the present disclosure further provide a display apparatus, comprising the display circuit above.

The embodiments of the present disclosure provide a display circuit and a display apparatus. The display circuit comprises a plurality of micro devices connected in a common anode manner or a common cathode manner. A cathode of each of the plurality of micro devices is connected to a first transistor, and an anode of the micro device is connected to a second transistor. The first transistor and the second transistor cooperate to generate a reverse bias voltage to initialize the micro device. In the embodiments of the present disclosure, the cathode and anode of each of the plurality of micro devices connected in a common anode manner or a common cathode manner are respectively connected to the first transistor and the second transistor, and a reverse bias voltage can be generated by the cooperation of the first transistor and the second transistor, so as to initialize the micro device. Under the light emission of a new sequence needing to be operated, charges left over from the previous operation sequence are eliminated, so that the background luminance caused by the residual charges is avoided, thereby improving the low luminance quality, and improving the contrast.

### BRIEF DESCRIPTION OF THE DRAWINGS

FIG. 1 is a diagram of a panel architecture adopting a common electrode structure according to the related art.

FIG. 2 is an equivalent circuit diagram of a panel architecture adopting a common cathode structure according to the related art.

FIG. 3 is an equivalent circuit diagram of a panel architecture adopting a common anode structure according to the related art.

FIG. 4 is a partial equivalent circuit diagram of a panel architecture adopting a common cathode structure according to the related art.

FIG. 5 is a sequence diagram after operation sequences in the related art.

FIG. 6 is an equivalent circuit diagram of a display circuit adopting a common cathode structure according to some embodiments of the present disclosure.

FIG. 7 is an equivalent circuit diagram of a display circuit adopting a common anode structure according to some embodiments of the present disclosure.

FIG. 8 is a partial equivalent circuit diagram of a display circuit adopting a common cathode structure according to some embodiments of the present disclosure.

FIG. 9 is a diagram of the electrical characteristics of an EL device according to some embodiments of the present disclosure.

FIG. 10 is a sequence diagram after operation sequences according to some embodiments of the present disclosure.

FIG. 11 is an equivalent circuit diagram of a display circuit adopting a common cathode architecture and comprising sub-circuit units according to some embodiments of the present disclosure.

FIG. 12 is an equivalent circuit diagram of a display circuit adopting a common anode architecture and comprising sub-circuit units according to some embodiments of the present disclosure.

FIG. 13 is an equivalent circuit diagram of a display circuit in which the EL devices in FIG. 11 are divided into a plurality of groups.

FIG. 14 is an equivalent circuit diagram of a display circuit in which the EL devices in FIG. 12 are divided into a plurality of groups.

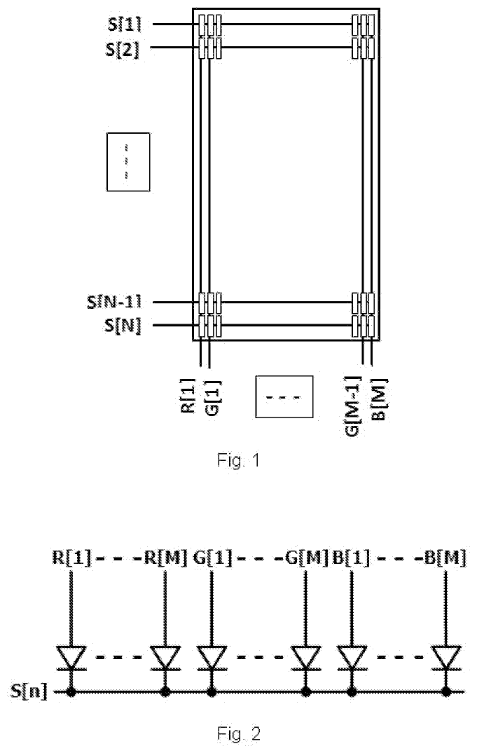

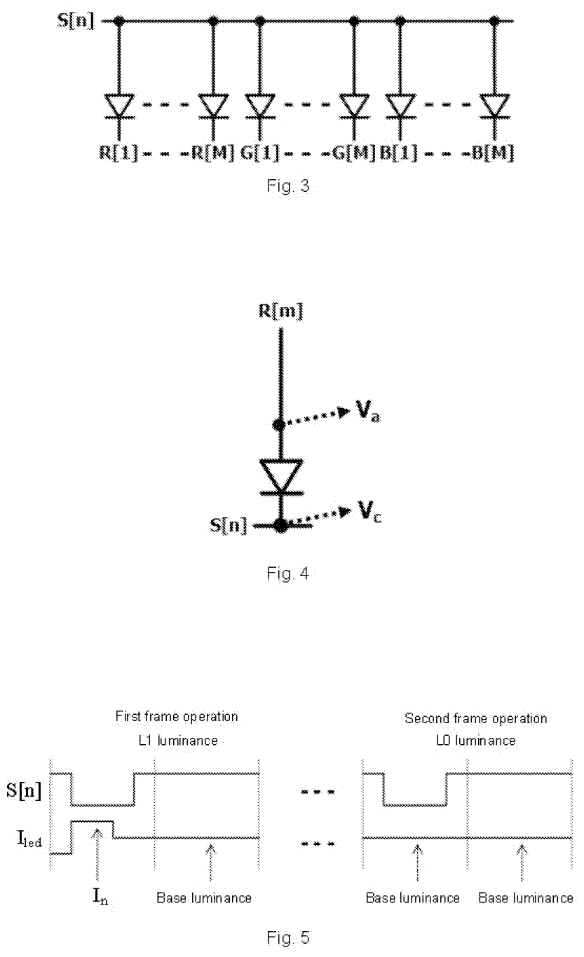

### DETAILED DESCRIPTION OF THE EMBODIMENTS

The Thin Film Transistor (TFT) backplane substrate is generally made using Low Temperature Poly-Silicon (LTPS) technology or the active device manufacturing process on metal oxide similar to the moldable rigid glass or flexible polyimide. Using this device, a functional circuit can be created for improving additional feature advantages of the display. The common electrode architecture used for light emission of the EL device is used as a substrate element, but does not present a greatest advantage in a display product of a thin film transistor (TFT) backplane substrate, and in particular, it fails to present an extremely high reliability capability for excellent optical specifications. Therefore, the embodiments of the present disclosure provide a display circuit and a display apparatus, which can achieve the purpose of high contrast of a display product by initializing the EL device through TFTs provided at the cathode and the anode of the EL device.

To make the objects, technical solutions, and effects of the present disclosure clearer and more comprehensible, the following further describes the embodiments of the present disclosure in detail with reference to the accompanying drawings and examples. It should be understood that the embodiments described herein are only intended to explain the present disclosure, but not to limit the present disclosure.

Within the scope of the embodiments and the patent, unless there are specific limitations to the articles in the text, the terms “a” and “the” may generally refer to a single or plural.

In addition, if there are descriptions related to “first” and “second” in the embodiments of the present disclosure, the descriptions of “first” and “second” are only for description purposes, and cannot be understood as indicating or implying the relative importance thereof or implicitly indicating the number of indicated technical features. Thus, the features defined by “first” and “second” may explicitly or implicitly comprise at least one of the features. In addition, the technical solutions of the embodiments can be combined with each other as long as the technical solution obtained through the combination can be implemented by a person skilled in the art. When the combination of the technical solutions is contradictory or cannot be implemented, it should be considered that the combination of the technical solutions does not exist, and is not within the scope of protection of the present disclosure.

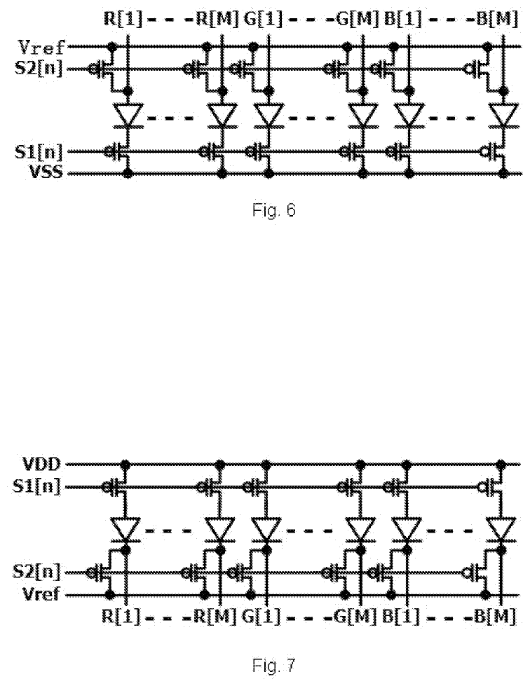

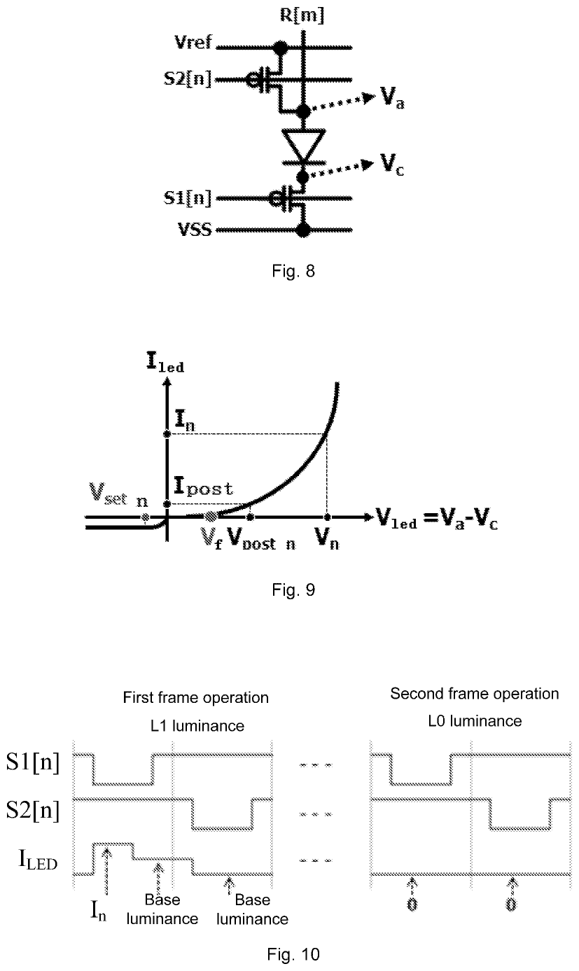

Referring to FIGS. 6 to 14, the present disclosure provides an exemplary embodiment of a display circuit.

As shown in FIGS. 6 and 7, the display circuit comprises a plurality of micro devices, and first transistors and second transistors which are connected to the plurality of micro devices. The plurality of micro devices are connected in a common anode manner or a common cathode manner. The first transistor is connected to a cathode of the micro device. The second transistor is connected to an anode of the micro device. The first transistor and the second transistor cooperate to generate a reverse bias voltage, so as to initialize the micro device. In the embodiments of the present disclosure, the first transistor and the second transistor are respectively connected to the cathode and anode of each of the plurality of micro devices connected in a common anode manner or a common cathode manner, and the first transistor and the second transistor cooperate to generate a reverse bias voltage, so as to initialize the micro device. Under the new sequence light emission that needs to be operated, charges left over from the previous operation sequence are eliminated, so that the background luminance caused by the residual charges is avoided, thereby improving the low luminance quality, and improving the contrast.

Specifically, the micro device may be an electroluminescence (EL) device, hereinafter referred to as an EL device. The first transistor and the second transistor may be any one of p-TFT, n-TFT, p-MOS, and n-MOS. In this embodiment, the first transistor and the second transistor are p-TFTs.

With continuing reference to FIG. 6, in an exemplary embodiment, when the EL devices are connected in a common cathode manner, a gate of the first transistor is connected to a first common scanning signal line, the first common scanning signal line is used for providing a first common scanning signal S1[n] in an nth row; a gate of the second transistor is connected to a second common scanning signal line, the second common scanning signal line is used for providing a second common scanning signal S2[n] at an nth row; a drain of the first transistor is connected to the cathode of the EL device, a source of the first transistor is connected to a common cathode power source signal line Vss, and the common cathode power source signal line Vss is used for providing a power source signal in a common cathode structure; a drain of the second transistor is connected to a direct current source signal line Vref of the micro device, the direct current source signal line Vref is used for providing a direct current source signal for initializing the EL device, and a source of the second transistor is connected to the anode of the EL device.

Please refer to FIG. 6, in the embodiment where the EL elements are connected in the common cathode manner, anodes of the EL devices are connected to grayscale control signal lines, wherein the grayscale control signal lines comprise red grayscale control signal lines, green grayscale control signal lines and blue grayscale control signal lines. For example, an anode of one EL device is connected to a red grayscale control signal line R[1], an anode of an Mth EL device is connected to a red grayscale control signal line R[M], wherein R[M] represents the Mth red grayscale control signal line in the vertical direction. For example, an anode of one EL device is connected to a green grayscale control signal line G[1], and an anode of an Mth EL device is connected to a green grayscale control signal line G[M], wherein G[M] represents the Mth green grayscale control signal line in the vertical direction. For example, an anode of one EL device is connected to a blue grayscale control signal line B[1], and an anode of an Mth EL device is connected to a blue grayscale control signal line B[M], wherein B[M] represents the Mth blue grayscale control signal line in the vertical direction.

Please refer to FIG. 7, when the plurality of micro devices are connected in the common anode manner, a gate of the first transistor is connected to a second common scanning signal line, the second common scanning signal line is used for providing a second common scanning signal S2[n] in an nth row, a gate of the second transistor is connected to a first common scanning signal line, the first common scanning signal line is used for providing a first common scanning signal S1[n] in the nth row, a drain of the first transistor is connected to the cathode of the EL device, a source of the first transistor is connected to a direct current source signal line Vref of the EL device, the direct current source signal line Vref is used for providing a direct current source signal for initializing the EL device, a drain of the second transistor is connected to a common anode power source signal line VDD, the common anode power source signal line VDD is used for providing a power source signal in a common anode architecture, and a source of the second transistor is connected to the anode of the EL device.

Please refer to FIG. 7, in the embodiment where the EL devices are connected in the common anode manner, grayscale control signal lines are connected to the cathodes of the EL devices. The grayscale control signal lines comprise red grayscale control signal lines, green grayscale control signal lines and blue grayscale control signal lines. For example, the cathode of one of the EL devices is connected to a red grayscale control signal line R[1], and the cathode of an Mth EL device is connected to a red grayscale control signal line R[M], wherein R[M] represents the Mth red grayscale control signal line in the vertical direction. For example, the cathode of one EL device is connected to a green grayscale control signal line G[1], and the cathode of an Mth EL device is connected to a green grayscale control signal line G[M], wherein G[M] represents the Mth green grayscale control signal line in the vertical direction. For example, the cathode of one EL device is connected to a blue grayscale control signal line B[1], and the cathode of an Mth EL device is connected to a blue grayscale control signal line B[M], wherein B[M] represents the Mth blue grayscale control signal line in the vertical direction.

The working principle of the embodiments of the present disclosure is further described in the following embodiments in which the EL elements are connected in a common cathode manner. As shown in FIGS. 7, 8, 9 and 10, under normal operations, after the previous sequence operation, that is, after the 1st frame operation, residual charges easily accumulate on the EL device, and at this time, the cross-voltage value Vled on the EL device is higher than Vf, wherein Vf is a preset comparison value, and Vled=Va−Vc. When the cross-voltage value Vled on the EL device is higher than Vf, a current is generated, thereby causing the generation of a base luminance lpostn, which further affects the minimum value of the LO luminance of the 2nd frame. That is to say, the residual charges are continuously supplied to the EL device to enable the EL device to emit light, causing the generation of the base luminance. In the embodiments of the present disclosure, in a common cathode architecture, a first transistor and a second transistor are respectively arranged on the cathode and anode of an EL device, it is set that Vref<Vss+Vf, after the first sequence operation (1st frame), by the cooperation of the first transistor and the second transistor, a reverse bias voltage with respect to the EL device is produced, thereby initializing the EL device such that the cross-voltage value Vled on the EL device is lower than Vf, and the current value of lled is 0. That is to say, after the previous sequence operation (1st frame), the EL device is subjected to an initialization procedure to eliminate residual charges of the EL device, so that the lowest value of the low grayscale or LO luminance can absolutely reach 0 luminance, so as to avoid that the base luminance lpostn affects the lowest value of LO luminance, thus, the absolute 0 luminance is achieved, and the contrast value is improved.

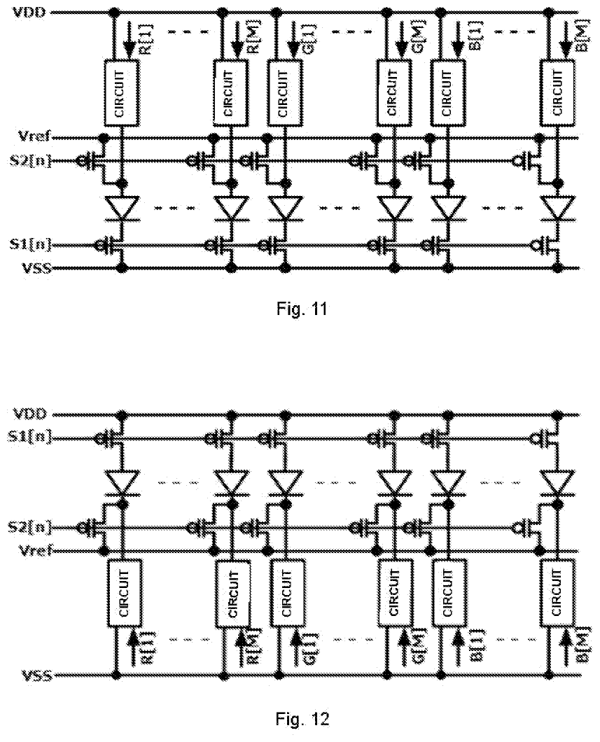

Please refer to FIG. 11, in an implementation where the EL devices are connected in a common cathode manner, the display circuit further comprises a plurality of sub-circuit units. The sub-circuit units (CIRCUIT) are arranged corresponding to the EL devices, one end of each of the plurality of sub-circuit units is connected to the common anode power source signal line VDD, the other end of the sub-circuit unit is connected to an anode of the EL device and a source of the second transistor, and the grayscale control signal line is connected to the sub-circuit unit. The sub-circuit unit is composed of a third transistor and a capacitor. The red grayscale control signal line, the green grayscale control signal line and the blue grayscale control signal line are connected to the plurality of sub-circuit units for controlling the gate of each third transistor or the capacitor nodes. Therefore, in a common cathode architecture, by connecting circuits (sub-circuit units) for other functions in series on the EL devices, specific requirements of a product can be satisfied. For example, when a sub-circuit unit is composed of a third transistor and a capacitor, the sub-circuit unit can be used for improving display quality.

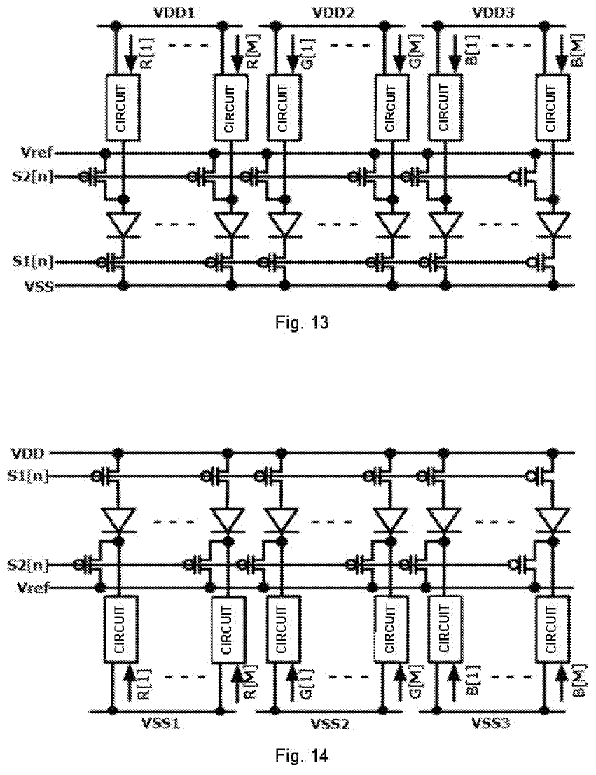

Please refer to FIG. 13, in the embodiment where the EL devices are connected in a common cathode manner, the display circuit comprises multiple groups of EL device components, each group of EL device components comprises a first transistor, a second transistor, an EL device, and a sub-circuit unit. The common anode power source signal line VDD comprises a first common anode power source signal line VDD1, a second common anode power source signal line VDD2, a third common anode power source signal line VDD3 and an Nth common anode power source signal line VDDN. One ends of the plurality of sub-circuit units are correspondingly connected to the first common anode power source signal line VDD1, the second common anode power source signal line VDD2, the third common anode power source signal line VDD3 and the Nth common anode power source signal line VDDN, respectively, and the other ends of the plurality of sub-circuit units are connected to the anodes of the plurality of EL devices, wherein N is an integer. By decomposing a group of electrodes into a plurality of groups of EL device components, the minimum across voltage required for the movement of each group of EL devices can be optimized, and when the across voltage is reduced, the power consumption can be reduced.

Please refer to FIG. 12, in the embodiment where the EL devices are connected in a common anode manner, the display circuit further comprises a plurality of sub-circuit units. The plurality of sub-circuit units are arranged corresponding to the plurality of EL devices. One end of each of the plurality of sub-circuit units is connected to the common cathode power source signal line VSS, the other end of the sub-circuit unit is connected to a cathode of the EL device and a drain of the first transistor, and the grayscale control signal line is connected to the sub-circuit unit. The sub-circuit unit is composed of a third transistor and a capacitor. The red grayscale control signal line, the green grayscale control signal line and the blue grayscale control signal line are connected to the plurality of sub-circuit units for controlling the gates of the third transistors or the capacitor nodes. Therefore, in a common anode architecture, by connecting circuits (sub-circuit units) for other functional purposes in series on the EL devices, specific requirements of a product can be satisfied. For example, when a sub-circuit unit is formed by a third transistor and a capacitor, the sub-circuit unit can be used for improving the display quality.

Please refer to FIG. 14, in the embodiment in which the EL devices are connected in a common anode manner, the display circuit comprises a plurality of groups of micro device components. Each group of micro device component comprises the first transistor, the second transistor, the micro device and the sub-circuit unit. The common cathode power source signal line comprises a first common cathode power source signal line VSS1, a second common cathode power source signal line VSS2, a third common cathode power source signal line VSS3, and an Nth common cathode power source signal line VSSN. One ends of the plurality of sub-circuit units are correspondingly connected to the first common cathode power source signal line VSS1, the second common cathode power source signal line VSS2, the third common cathode power source signal line VSS3 and the Nth common cathode power source signal line VSSN, respectively, and the other ends of the plurality of sub-circuit units are connected to the anodes of the plurality of EL devices, wherein N is an integer. By decomposing a group of electrodes into a plurality of groups of EL device components, the minimum across voltage required for the movement of each group of EL devices can be optimized, and when the across voltage is reduced, the power consumption can be reduced.

The embodiments of the present disclosure further provide a display apparatus. Referring to FIGS. 6 to 14, the display apparatus comprises a display circuit, wherein the display circuit comprises a plurality of micro devices connected in a common anode manner or a common cathode manner. A cathode of each of the plurality of micro devices is connected to a first transistor, an anode of the micro device is connected to a second transistor, and the first transistor and the second transistor cooperate to generate a reverse bias voltage to initialize the micro device. The details are as described above, and will not be described herein again.

In conclusion, the embodiments of the present disclosure provide a display circuit and a display apparatus. The display circuit comprises a plurality of micro devices connected in a common anode manner or a common cathode manner, wherein a cathode of each of the plurality of micro devices is connected to a first transistor, an anode of the micro device is connected to a second transistor, and the first transistor and the second transistor cooperate to generate a reverse bias voltage to initialize the micro device. In the embodiments of the present disclosure, the first transistor and the second transistor are respectively connected to the cathode and anode of each of the plurality of micro devices connected in a common anode manner or a common cathode manner, and the first transistor and the second transistor cooperate to generate a reverse bias voltage, so as to initialize the micro device. Under the new sequence light emission that needs to be operated, charges left over from the previous operation sequence are eliminated, so that the background luminance caused by the residual charges is avoided, thereby improving the low luminance quality, and improving the contrast.

It should be understood that the application of the embodiments of the present disclosure is not limited to the examples above. Those skilled in the art can make improvements or modifications according to the above descriptions. All these improvements and modifications shall belong to the scope of protection of the appended claims of the present disclosure.

What is claimed is:

1. A display circuit, comprising a plurality of micro devices connected in a common anode manner or a common cathode manner, wherein a cathode of each of the plurality of micro devices is connected to a first transistor, an anode of the micro device is connected to a second transistor, and the first transistor and the second transistor cooperate to generate a reverse bias voltage to initialize the micro device.

2. The display circuit according to claim 1, wherein when the plurality of micro devices are connected in the common cathode manner, a gate of the first transistor is connected to a first common scanning signal line, and a gate of the second transistor is connected to a second common scanning signal line; a drain of the first transistor is connected to the cathode of the micro device, and a source of the first transistor is connected to a common cathode power source signal line; a drain of the second transistor is connected to a direct current source signal line of the micro device, and a source of the second transistor is connected to the anode of the micro device.

3. The display circuit according to claim 2, wherein anodes of the plurality of micro devices are connected to grayscale control signal lines, wherein the grayscale control signal lines comprise red grayscale control signal lines, green grayscale control signal lines and blue grayscale control signal lines.

4. The display circuit according to claim 2, further comprising a plurality of sub-circuit units, wherein the plurality of sub-circuit units are arranged corresponding to the plurality of micro devices; one end of each of the plurality of sub-circuit units is connected to the common anode power source signal line, and the other ends of the plurality of sub-circuit units are connected to anodes of the plurality of micro devices and the source of the second transistor; a grayscale control signal line is connected to the sub-circuit unit; and the sub-circuit unit is composed of a third transistor and a capacitor.

5. The display circuit according to claim 4, comprising multiple groups of micro device components, wherein each of the multiple groups of micro device components comprises the first transistor, the second transistor, the micro device, and the sub-circuit unit; the common anode power source signal line comprises a first common anode power source signal line, a second common anode power source signal line, a third common anode power source signal line and an Nth common anode power source signal line; one ends of the plurality of sub-circuit units are correspondingly connected to the first common anode power source signal line, the second common anode power source signal line, the third common anode power source signal line and the Nth common anode power source signal line, respectively, and the other ends of the plurality of sub-circuit units are connected to anodes of the plurality of micro devices, wherein N is an integer.

6. The display circuit according to claim 1, wherein when the plurality of micro devices are connected in the common anode manner, a gate of the first transistor is connected to a second common scanning signal line, and a gate of the second transistor is connected to a first common scanning signal line; a drain of the first transistor is connected to the cathode of the micro device, and a source of the first transistor is connected to a direct current source signal line of the micro device; a drain of the second transistor is connected to a common anode power source signal line, and a source of the second transistor is connected to the anode of the micro device.

7. The display circuit according to claim 6, wherein cathodes of the plurality of micro devices are connected with grayscale control signal lines, wherein the grayscale control signal lines comprise red grayscale control signal lines, green grayscale control signal lines and blue grayscale control signal lines.

8. The display circuit according to claim 6, further comprising a plurality of sub-circuit units, wherein the plurality of sub-circuit units are arranged corresponding to the plurality of micro devices; one end of each of the plurality of sub-circuit units is connected to the common cathode power source signal line, and the other end of the sub-circuit unit is connected to the cathode of the micro device and the drain of the first transistor; a grayscale control signal line is connected to the sub-circuit unit; and the sub-circuit unit is composed of a third transistor and a capacitor.

9. The display circuit according to claim 8, comprising multiple groups of micro device components, wherein each of the multiple groups of micro device components comprises the first transistor, the second transistor, the micro device, and the sub-circuit unit; the common cathode power source signal line comprises a first common cathode power source signal line, a second common cathode power source signal line, a third common cathode power source signal line, and an Nth common cathode power source signal line; one ends of the plurality of sub-circuit units are correspondingly connected to the first common cathode power source signal line, the second common cathode power source signal line, the third common cathode power source signal line and the Nth common cathode power source signal line, respectively, and the other ends of the plurality of sub-circuit units are connected to cathodes of the plurality of micro devices, wherein N is an integer.

10. The display circuit according to claim 1, wherein the first transistor and the second transistor are one or more of a p-channel Thin Film Transistor (p-TFT), an n-channel TFT (n-TFT), a p-channel Metal Oxide Semiconductor (p-MOS), and an n-channel MOS (n-MOS).

11. The display circuit according to claim 1, wherein the plurality of micro devices are electroluminescent devices.

12. A display apparatus, comprising a display circuit, wherein the display circuit comprises a plurality of micro devices connected in a common anode manner or a common cathode manner, a cathode of each of the plurality of micro devices is connected to a first transistor, an anode of the micro device is connected to a second transistor, and the first transistor and the second transistor cooperate to generate a reverse bias voltage to initialize the micro device.

13. The display circuit according to claim 3, further comprising a plurality of sub-circuit units, wherein the plurality of sub-circuit units are arranged corresponding to the plurality of micro devices; one end of each of the plurality of sub-circuit units is connected to the common anode power source signal line, and the other ends of the plurality of sub-circuit units are connected to anodes of the plurality of micro devices and the source of the second transistor; the grayscale control signal line is connected to the sub-circuit unit; and the sub-circuit unit is composed of a third transistor and a capacitor.

14. The display circuit according to claim 13, comprising multiple groups of micro device components, wherein each of the multiple groups of micro device components comprises the first transistor, the second transistor, the micro device, and the sub-circuit unit; the common anode power source signal line comprises a first common anode power source signal line, a second common anode power source signal line, a third common anode power source signal line and an Nth common anode power source signal line; one ends of the plurality of sub-circuit units are correspondingly connected to the first common anode power source signal line, the second common anode power source signal line, the third common anode power source signal line and the Nth common anode power source signal line, respectively, and the other ends of the plurality of sub-circuit units are connected to anodes of the plurality of micro devices, wherein N is an integer.

15. The display circuit according to claim 7, further comprising a plurality of sub-circuit units, wherein the plurality of sub-circuit units are arranged corresponding to the plurality of micro devices; one end of each of the plurality of sub-circuit units is connected to the common cathode power source signal line, and the other end of the sub-circuit unit is connected to the cathode of the micro device and the drain of the first transistor; the grayscale control signal line is connected to the sub-circuit unit; and the sub-circuit unit is composed of a third transistor and a capacitor.

16. The display circuit according to claim 15, comprising multiple groups of micro device components, wherein each of the multiple groups of micro device components comprises the first transistor, the second transistor, the micro device, and the sub-circuit unit; the common cathode power source signal line comprises a first common cathode power source signal line, a second common cathode power source signal line, a third common cathode power source signal line, and an Nth common cathode power source signal line; one ends of the plurality of sub-circuit units are correspondingly connected to the first common cathode power source signal line, the second common cathode power source signal line, the third common cathode power source signal line and the Nth common cathode power source signal line, respectively, and the other ends of the plurality of sub-circuit units are connected to cathodes of the plurality of micro devices, wherein N is an integer.

17. The display apparatus according to claim 12, wherein when the plurality of micro devices are connected in the common cathode manner, a gate of the first transistor is connected to a first common scanning signal line, and a gate of the second transistor is connected to a second common scanning signal line; a drain of the first transistor is connected to the cathode of the micro device, and a source of the first transistor is connected to a common cathode power source signal line; a drain of the second transistor is connected to a direct current source signal line of the micro device, and a source of the second transistor is connected to the anode of the micro device.

18. The display apparatus according to claim 17, wherein anodes of the plurality of micro devices are connected to grayscale control signal lines, wherein the grayscale control signal lines comprise red grayscale control signal lines, green grayscale control signal lines and blue grayscale control signal lines.

19. The display apparatus according to claim 12, wherein when the plurality of micro devices are connected in the common anode manner, a gate of the first transistor is connected to a second common scanning signal line, and a gate of the second transistor is connected to a first common scanning signal line; a drain of the first transistor is connected to the cathode of the micro device, and a source of the first transistor is connected to a direct current source signal line of the micro device; a drain of the second transistor is connected to a common anode power source signal line, and a source of the second transistor is connected to the anode of the micro device.

20. The display apparatus according to claim 19, wherein cathodes of the plurality of micro devices are connected with grayscale control signal lines, wherein the grayscale control signal lines comprise red grayscale control signal lines, green grayscale control signal lines and blue grayscale control signal lines.
